(19) United States
(12) Patent Application Publication
(10) Pub. No.: US 2008/0308303 A1
(43) Pub. Date: Dec. 18, 2008

(54) Chip carrier substrate and production method therefor

(76) Inventors: Volker Lehmann, Munich (DE); Florian Binder, Buchendorf (DE); Thomas Haneder, Dachau (DE); Alfred Martin, Munich (DE); Judith Lehmann, Munich (DE)

Correspondence Address: DICKSTEIN SHAPIRO LLP, 1177 AVENUE OF THE AMERICAS 6TH AVENUE, NEW YORK, NY, 10036-2714, US

(21) Appl. No.: 11/486,671

(22) Filed: Jul. 14, 2006

(30) Foreign Application Priority Data
Jul. 15, 2005 (DE) 102005033254.4-33

(51) Int. Cl. H05K 1/03; H05K 3/10

(52) U.S. Cl. 174/255; 29/846

(57) ABSTRACT

Method for producing a macroporous silicon substrate suitable as a carrier for microelectronic components. Blind holes are produced from a front surface of the substrate. An insulator layer is produced on the front and rear surfaces of the substrate. Selective isotropic etching is performed from the rear surface with uncovering of blind hole ends produced such that respective blind hole walls formed by the insulator layer project from the substrate on the rear surface and are defined in this region only by the insulator layer forming the respective blind hole wall. A further insulator layer is then produced on the surfaces of the substrate. A plurality of the blind holes are then filled with a metal or a metal alloy by introducing the substrate into a melt thereof under pressure in a process chamber containing the melt. The melt is then asymmetrically cooled in the blind holes from the front surface, so that the metal or the alloy contracts toward and lies on a plane with the rear surface of the substrate. Any of the remaining unfilled blind hole ends that project from the substrate are removed.

### CROSS-REFERENCE TO RELATED APPLICATION

This application claims priority to German Patent Application Serial No. 10 2005 033 254.4, filed on Jul. 15, 2005, and is incorporated herein by reference in its entirety.

### FIELD OF THE INVENTION

The present invention relates to a macroporous silicon substrate suitable as a carrier for microelectronic components, and a method for producing the macroporous silicon substrate.

### BACKGROUND OF THE INVENTION

The present invention describes in particular a method for producing a chip carrier substrate made of silicon with continuous contacts. The present invention constitutes an innovative technology platform for the production of large scale integrated “system in package” modules based on silicon carriers and is applied in the field of communications technology and automotive and industrial electronics (e.g. radiofrequency modules for mobile telephones, base stations or else radar modules for automobiles) or other fields in which extremely large scale integration is desirable for space or cost reasons.

“System in Package” modules are currently produced using various carrier materials such as, for example, LTCC ceramic, laminate PCB, glass or silicon. One challenge when using silicon carriers consists in the production of so-called “through holes”, that is to say plated-through holes in the carrier. Various “through hole” technologies are available nowadays for the production of prototypes. A significant disadvantage of the previous concepts consists, however, in the great technical complexity and the associated production costs.

In this case, a particular problem in the production of such chip carrier substrates consists in producing the electrical connections leading through the substrate through both sides of the substrate, so-called vias, that is to say in filling holes leading through the substrate with metal. The filling of vias with metal becomes more and more difficult as the aspect ratio increases, that is to say as the diameter decreases and the depth increases. Calculations show, however, that vias having a large aspect ratio are particularly desirable. This is because in many application-relevant cases it is particularly advantageous for the electrical properties for a plurality of smaller contact holes e.g. having a diameter of 10 μm to be connected in parallel instead of one contact hole having a diameter of e.g. 100 μm. This improves the electrical conductivity of the vias whenever AC voltage or AC current, as is the case for example with high-frequency signals, is to be passed through the substrate. In this case, on account of the so-called skin effects, only that region of the conductor, that is to say of the via, which is near the surface is available for signal transport. Connecting a plurality of smaller vias in parallel constitutes a major advantage insofar as more surface is made available for signal transport and in the case of a large via, which significantly improves particularly the radiofrequency properties in the GHz range. In the range of a few ten of GHz, it is connecting a plurality of vias in parallel that actually makes electrically good through-plating possible in the first place.

A further problem in the use of a conductive substrate material such as silicon consists in the production of an insulator layer by which the contacts passing through the substrate are extremely reliably insulated both from one another and from the substrate itself. The process would normally be conducted such that firstly metal-filled blind holes are produced in the substrate and part of the substrate material is removed from the rear side by etching back or grinding the substrate in order to open the contact holes from the rear side and make them accessible. In particular when grinding the material back, the problem occurs in this case that, as a result of smearing of the metal from the contact holes on the rear side of the substrate, a short circuit may arise between contact holes or contact holes and substrate, which leads to the failure of the chip carrier substrate. The fact of an electrically conductive connection arising between metal in the contact hole and substrate cannot be precluded in the case of etching back either. This is because with this type of process implementation the insulator layer on the rear side of the substrate is always produced after the contact holes have been filled with metal; that is to say that the arising of an unintentional short circuit between the metal in the contact holes or the metal in the contact holes and the substrate on the rear side of the chip carrier substrate, which leads to the failure of the chip carrier substrate, cannot be prevented by the insulator layer on the rear side. This problem may lead to considerable yield problems in the production of such chip carrier substrates.

Consequently, the present invention realizes, in the context of providing such “system in package” modules, the plated-through holes of the carrier material used therefor with good electrical conductivity and in a cost-effective and efficient manner. In particular, the present invention also specifies a method which efficiently and cost-effectively permits the filling of the contact holes with metal even in the case of small hole diameters, that is to say of realizing metal-filled contact holes having a large aspect ratio. The present invention also specifies a process implementation which permits the production of an insulator layer on all surfaces of the chip carrier substrate before the contact holes are filled with metal.

### SUMMARY OF THE INVENTION

The present invention provides a method for producing a metal-filled or alloy-filled substrate based on macroporous silicon which is suitable as a carrier for microelectronic components, in particular chips, comprising the following steps:

(i) production of blind holes having a depth in the range of 25 to 1000 μm, preferably 100 to 250 μm, and a diameter in the range of 5 to 150 μm, preferably 5 to 30 μm, from the first front-side surface of a silicon substrate,
(ii) production of an insulator layer on the surfaces of the substrate obtained in step (i),
(iii) selective isotropic etching from the second, rear-side surface with uncovering of the blind hole ends produced in step (ii) in such a way that the respective blind hole walls formed by the insulator layer produced in step (ii) project from the substrate on the rear-side surface and are defined in this region only by the insulator layer forming the respective blind hole wall, which may in turn be set by way of the length of the projecting insulator layer,
(iv) production of a further insulator layer on the surfaces of the substrate obtained in step (iii),
(v) filling of at least a multiplicity, that is to say at least 50 to 100%, of the blind holes produced with metal by introduction of the substrate obtained in step (iii) or (iv) into a melt thereof under pressure in a process chamber containing the melt,
(vi) asymmetrical cooling of the melt in the blind holes from the front-side surface, so that the metal contracts upon cooling in the blind holes toward the rear-side surface until the solidified metal surface lies on a plane with the rear-side surface of the substrate, and
(vii) removal of the remaining unfilled blind hole ends that project from the substrate and are formed only by the insulator layer in this region.

If appropriate, after step (iii) or before step (iv), provision may be made for mechanically or chemically removing the insulator layer projecting from the substrate in the regions in which the pores are not intended to be filled with metal, in order to insulate the metal layers on both surfaces of the substrate from one another.

A further subject matter of the present invention relates to a metal-filled or alloy-filled substrate based on macroporous silicon, suitable as a carrier for microelectronic components, in particular chips, the substrate having a first and second surface situated oppositely, a multiplicity of discrete passage holes having a diameter in the range of 5 to 150 μm being arranged in a manner distributed over the entire surface region, the surfaces and the inner walls of the passage holes of the substrate being covered by an insulator layer, and the passage holes being completely filled with metal or a metal alloy, so that the metal-filled passage holes, as vias, electrically contact-connect the metallization planes of the first and second surfaces to one another, the contacts in each case being electrically insulated from one another and, moreover, each contact being electrically insulated from the substrate.

In one preferred embodiment, the metal for filling the passage holes is selected from aluminum or an alloy thereof with silicon or copper. The insulator layer is preferably based on SiO₂ or Si₃N₄.

The thickness of such a substrate according to the invention is usually between 25 and 1000 μm, preferably between 100 and 250 μm. The density of the filled passage holes preferably lies in the range of 10⁴ to 10⁶/cm². An aspect ratio in the range of 1:5 to 1:50 can usually be realized by means of the method according to the invention.

The substrate according to the invention constitutes a universally usable chip carrier for the mounting of a plurality of microelectronic components (that is to say dies, preferably made of silicon) which connects the components to one another with very good electrical conductivity and thermal conductivity, has very good reliability properties, is thermally stable up to 450° C. and can be produced cost-effectively.

The concept underlying the present invention is distinguished, moreover, by the following advantages:
high reliability of the insulator layer, since the insulator can be deposited on all surfaces actually prior to the metallization in the case of the process implementation according to the invention and no longer has to be removed. As a result, it is possible, for example, to use SiO₂ produced by thermal oxidation, which has a higher reliability and better dielectric properties in comparison with SiO₂ produced by means of a CVD process;
the central processes of pore etching and metallization of the blind holes or pores can be realized extremely cost-effectively;
short process chain through skillful process implementation;
innovative, fast metallization of the blind holes or pores;
use of known standard materials, as a result high reliability;
compatible with standard methods and apparatuses of the semiconductor industry;
good electrical conductivity of the plated-through holes, particularly if aluminum is used as metal for filling the passage holes; and
high thermal stability of the finished carrier favorable for subsequent “bond” and “cut” processes.

The fundamental use of silicon as carrier material has the following advantages:
excellent thermal conductivity of the substrate
high integration density for high density packaging, since “backend of line” processes can be used
matched coefficient of expansion between chip and chip carrier.

The problem of wiring individual microelectronic components or silicon chips is solved by the silicon substrate according to the invention, which is metallized locally on both sides, wherein both metal planes, that is to say those on the first, front-side and second, rear-side surfaces, are in this case connected to one another with good electrical conductivity by means of metal-filled passage holes that function as vias.

The advantage of the method according to the invention or of the substrate obtainable thereby consists first of all in the fact that the thermal conductivity of silicon (˜148 W/m K) is much greater than that of conventional printed circuit boards. The thermal conduction of the entire construction comprising a plurality of silicon chips which can be electrically conductively connected by the chip carrier according to the invention by means of defined contacts and conductor tracks is therefore significantly improved. The dissipation of heat can be significantly increased in this way and fewer problems due to overheating of the microelectronic components occur (e.g. reliability problems due to electromigration).

Furthermore, the use of a chip carrier made of silicon, as provided according to the invention, results in a matching of the coefficients of thermal expansion of the entire construction. Since both the carrier and the microelectronic chips are then composed of the same material and the good thermal conduction greatly reduces corresponding temperature gradients, there are no appreciable mechanical stresses in the construction either at a constant temperature or in the event of temperature variations.

With the use of aluminum, in particular, as material for the through-plating of the substrate or chip carrier according to the invention, not only is a very good electrical conductivity achieved but in addition the possibility is opened up of coating the surfaces of the chip carrier with thin metal films or insulators by means of conventional processes such as sputtering or CVD methods at temperatures of up to approximately 450° C. and in this way producing conductor tracks or producing them thereon.

The production method according to the invention additionally enables a very much more cost-effective production in comparison with conventional methods in the semiconductor industry.

### BRIEF DESCRIPTION OF THE DRAWINGS

In the figures:

FIG. 1 schematically shows the essential method steps for the production of a preferred embodiment of the substrate according to the invention.

FIG. 2 shows the substrate according to the invention with conductor tracks arranged photolithographically thereon.

FIG. 3 shows an exemplary application of the chip carrier according to the invention in conjunction with customary standard flip-chip interconnects and a face-to-face interconnect.

### DETAILED DESCRIPTION OF PREFERRED EMBODIMENTS OF THE INVENTION

The production method according to the invention is explained in more detail below.

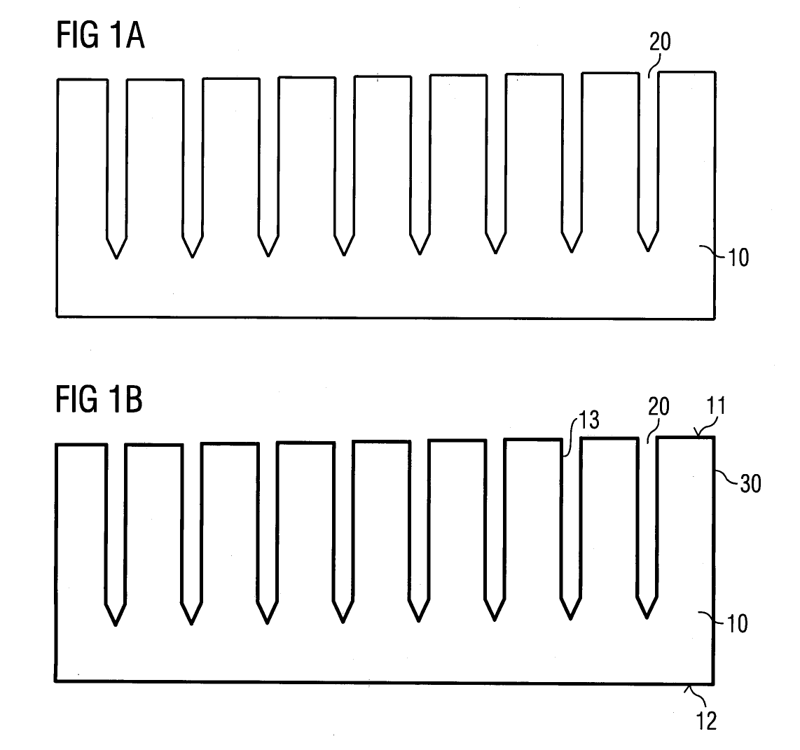

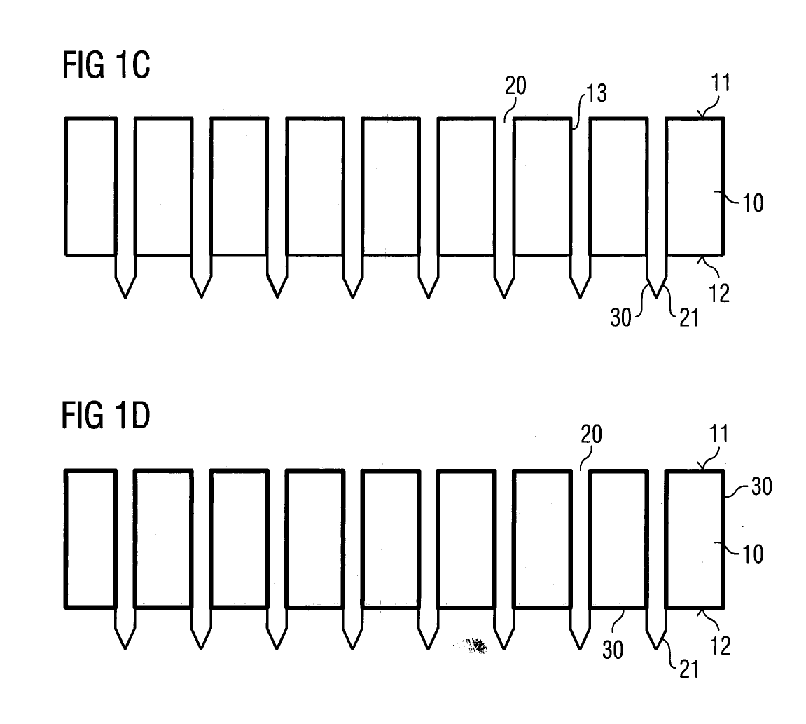

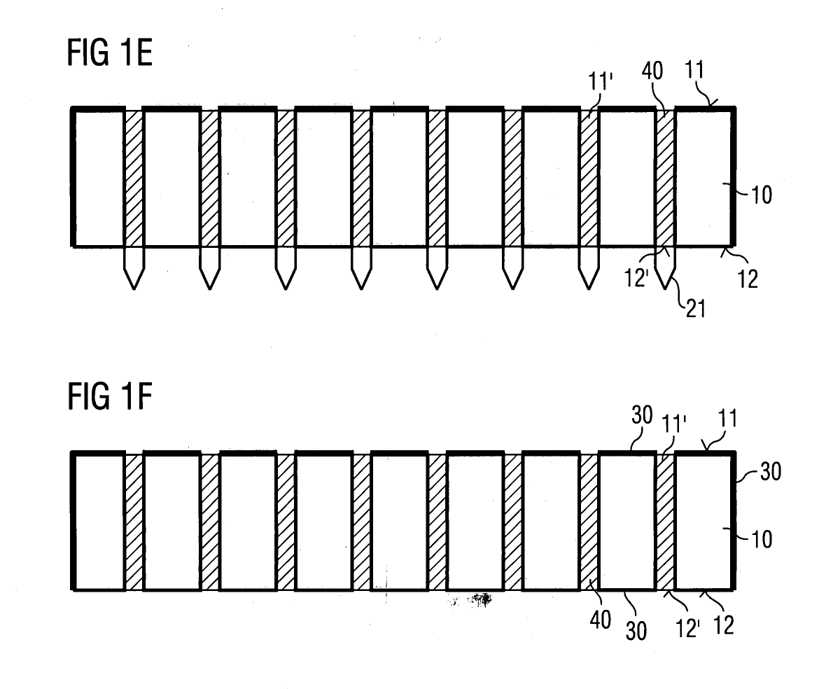

Preferably lightly n- or p-doped (˜1000 ohms cm) silicon is used for the production of the chip carrier according to the invention. The parasitic capacitance of the substrate is particularly low as a result. The production of the vias or contact holes, which subsequently connect one metallized side of the carrier substrate to the other metallized side of the substrate, is preferably effected by electrochemical etching as described e.g. in EP-A1-0 296 348 or in V. Lehmann, J. Electrochem. Soc. 140, 1993, page 2836 et seq. As an alternative, the pores can also be produced by other etching methods known in micromechanics, such as reactive ion etching (RIE) or laser drilling. The blind holes or pores thus produced in the substrate material have a depth in the range of 25 to 1000 μm, preferably 100 to 250 μm. In this case, the diameter of the pores lies in the range of 5 to 150 μm, preferably between 5 and 30 μm. FIG. 1A shows the substrate 10 made of silicon with the corresponding blind holes 20 after carrying out step (i) in accordance with the method of the present invention.

Afterward, in accordance with step (ii) an insulator layer 30, preferably a silicon dioxide produced by thermal oxidation, is applied to the surfaces of the substrate that has been prepared in this way. However, it is also possible to use other methods and insulator materials, e.g. SiO₂ that is sputtered or produced from TEOS (tetraethyl orthosilicate) by means of a chemical vapor deposition method (CVD) or silicon nitride produced from silane (SiH₄) and ammonia (NH₃). The thickness of the insulator layer is preferably in the range of 10 to 2000 nm, more preferably between 100 and 500 nm. In this case, the insulator layer 30 covers all surfaces of the substrate, that is to say the first surface (front side) 11 and the second surface (rear side) 12 and also the inside of the blind holes or pores 13. FIG. 1B shows the substrate 10 after carrying out step (ii) in accordance with the method of the present invention.

After the production of the insulator layer, the blind holes 20 produced from the first, front-side surface 11 are uncovered by selective isotropic etching from the second, rear-side surface 12, to be precise in such a way that the insulator layer 30 is preserved in the blind holes and in particular at the blind hole ends, and only the silicon is removed (cf. FIG. 1C). For this purpose, the insulator layer 30 is removed from the second, rear-side surface 12 by wet- or dry-chemical etching and the silicon is subsequently etched on one side, e.g. wet-chemically using KOH or TMAH. As an alternative, a first part of the silicon may also be removed by mechanical grinding or lapping and a wet- or dry-chemical method may subsequently be used in order to uncover the insulator layer in the blind holes nondestructively. FIG. 1C shows the substrate 10 with the blind hole ends 21 uncovered in regions after carrying out step (iii) in accordance with the method of the present invention. In the region in which the blind holes are uncovered, the latter are defined only by the insulator layer that was not removed during the etching back of the silicon. Even when the insulator has layer thicknesses of 200 nm or less, it is possible to remove the silicon over the entire area of the wafer in a controlled manner without damaging the insulator layer. The height of the uncovered part of the blind holes typically corresponds to between 5 and 30% of the remaining wafer thickness. Given a residual wafer thickness of 250 μm, the height of the region of the blind holes which projects beyond the substrate and is defined by the insulator layer is e.g. between 10 and 50 μm, preferably approximately 30 μm. Surprisingly, the regions of the blind holes which are defined by the insulator layer are mechanically very stable and free of defects despite the large ratio of height (e.g. 30 μm) to the layer thickness of the insulator (e.g. 200 nm).

Afterward, all surfaces of the substrate are provided with a further insulator layer 30, in particular the second, rear-side surface 12 on which the insulator layer was removed. This process step is preferably effected by thermal oxidation of the silicon. However, it is also possible to use other methods and insulator materials or combinations of methods and materials, e.g. SiO₂ that is sputtered or produced from TEOS (tetraethyl orthosilicate) by means of a chemical vapor deposition method (CVD) or silicon nitride that is produced from silane (SiH₄) and ammonia (NH₃). The thickness of the insulator layer is preferably in the range of 10 to 1000 nm, more preferably between 100 and 500 nm. In this case, the insulator covers all surfaces of the substrate, the first surface 11 and the second surface 12 and also the inside of the blind holes or pores 21 (cf. FIG. 1D). In partial regions of the substrate, this second insulator layer results in an increase in the total thickness of the insulator, namely where the first insulator layer was not removed. The previously applied insulator layer, e.g. SiO₂, grows further at these locations. FIG. 1D shows the substrate 10 with the blind holes 21 uncovered in regions after carrying out step (iv) in accordance with the method of the present invention.

This type of process implementation gives rise to blind holes or pores which project from the silicon substrate on the side of the second surface 12 and are defined in this region only by the insulator layer 30. This type of closed pores constitutes blind holes which are suitable for being filled in a melt under pressure with a liquid metal or an alloy comprising two or more metals 40 or semiconductors, such as e.g. AlSiCu, as described in V. Lehmann, Sensors and Actuators A95, 2002, page 202 et seq.

It is noted that pores which are open on both sides and the inner area of which does not exhibit wetting for the metal melt cannot be filled with liquid metal on account of capillary forces. This effect can be utilized advantageously in the method according to the invention. By locally removing the projecting part of the pores that is defined only by the insulator, e.g. by photolithographic patterning and subsequent etching or by means of a laser or by mechanical action (scraping, scribing, sawing or grinding), it is possible to define regions in which the pores are not filled with metal. These regions in which no electrically conductive connection arises between the two surfaces of the substrate on account of the pores not filled with metal can be used in particular for insulating the first metal plane on the first surface of the substrate from the first metal plane on the second surface. This is because if all the pores distributed homogeneously over the substrate are filled with metal, then the metallized contact holes, in the regions in which an electrically conductive connection from the front side to the rear side of the substrate is not intended to arise (e.g. at locations at which the conductor tracks cross on the front and rear sides), have to be covered with an insulator layer on at least one surface in order to prevent short circuits.

These metal-free regions additionally enable a large substrate or wafer to be singulated to form individual chips by means of conventional sawing, e.g. using a diamond saw blade. This is because if the pores in the substrate region removed by the saw blade were filled with metal, that would lead to a smearing of the metal on the saw blade. As a result, the saw blade would lose its normal function or saw blade and substrate would highly probably be destroyed. With regard to the electrical and magnetic properties of the chip carrier substrate, too, it may be advantageous to define regions in which, on the one hand, the pores are not filled with metal but, on the other hand, the substrate material has been removed by etching of the pores. As a result, e.g. the average relative permittivity of the substrate is reduced, as a result of which it is possible to reduce parasitic capacitances between conductor tracks and substrate.

For the purpose of filling the blind holes 20, the substrate 10 is introduced into a gastight process chamber containing the melt. While the chamber is evacuated, the substrate is situated above the surface of the melt. Once the desired pressure in the range of usually 1 to 100 mbar, preferably in the range of 10 to 50 mbar, has been reached, the substrate is dipped into the melt and pressure is applied to the process chamber. The pressure is preferably in the range of 1 to 20 bar, more preferably in the range of 5 to 10 bar. In this case, the required pressure depends on the process temperature, the surface tension of the metal used or of the alloy used and the diameter of the pores. By applying high pressure to the process chamber, the liquid metal melt is forced into the previously evacuated blind holes. Surprisingly, the regions of the pores which are defined only by the insulator layer on the rear side of the substrate readily withstand this type of process implementation. While the substrate is pulled from the metal melt, the high pressure is maintained in the process chamber.

In one preferred embodiment, the melt is made of (hypereutectic) aluminum which may e.g. also be alloyed with silicon and/or copper. A low melting point of less than 600° C., a good conductivity of the filled pores or blind holes and a good chemical compatibility between silicon dioxide, silicon nitride and silicon are thereby achieved.

In a further preferred embodiment, high-purity dry nitrogen or a high-purity dry noble gas such as argon is used as process gas in the process chamber for generating the pressure in the course of filling with liquid metal. It is thereby possible to prevent the surface of the liquid metal from forming an oxide layer or slag, which makes it more difficult for small pores to be filled and reduces the yield. In addition, it is possible to incorporate into the process chamber a mechanical device which permits the surface of the metal melt to be cleaned by a thermally stable scraper made of metal or ceramic being dipped somewhat into the melt and being pushed or pulled from one side of the melting crucible to the other side over the entire surface of the melt.

In the case of asymmetrical cooling of the melt in the pores or blind holes from the side of the first surface 11, the melt firstly solidifies at the first surface. In this case, the first substrate surface 11 lies on a plane with the first surface of the solidified metal 11′ in the pores or blind holes (cf. FIG. 1E). The process chamber is usually configured in such a way that it is possible to control the solidification of the metal in the pores. After the substrate has been pulled from the melt, the cooling of the first surface (side of the pore opening) may be accelerated e.g. by means of a water-cooled metal plate opposite the surface. The cooling of the melt from the rear side of the substrate is prevented or slowed down e.g. by means of a lamp heating system or a heated metal surface. What can thereby be achieved is that the metal solidifies in the pores from the front side toward the rear side. As the cooling progresses further, the material is drawn into the blind hole, so that the material 40 contracts upon cooling in the pores toward the side of the first surface 11. The process is usually conducted in such a way that the material 40 contracts to an extent such that the solidified surface 12′ lies on a plane with the second surface 12 of the substrate 10. This may be achieved by setting the length of the projecting part of the pores which is defined only by the insulator layer such that the volume of the part corresponds approximately to the volume difference between the volume of the liquid melt and the volume of the solidified metal at room temperature. In the liquid state, therefore, the metal fills the entire pore including the region of the pore which is defined only by the insulator layer. As a result of contraction of the metal during asymmetrical cooling in the region of the substrate, the metal is gradually drawn from the region of the pore which is defined only by the insulator layer into the region of the substrate. The pressure may also be used for setting the metal volume and hence the height of the solidified metal surface. Depending on the pressure to which the chamber is evacuated prior to the filling process and the magnitude of the pressure in the process chamber during the filling of the pores, the liquid metal fills the entire pore or only a part thereof. Only after solidification is the pressure reduced to normal pressure. FIG. 1E shows the substrate 10 after carrying out step (vi) in accordance with the method of the present invention.

This type of metal filling of pores or blind holes permits a significantly higher throughput per unit time and significantly lower process costs than conventional types of metal filling from the gas phase (CVD) or electrochemical or chemical plating. CVD methods can only be used to a limited extent owing to the high aspect ratio that is customarily sought and owing to the low deposition rates. On the one hand, a homogeneous deposition at the bottom of the blind holes is not possible on a production scale according to the prior art; on the other hand, the deposition rates that can be achieved are so low that extremely long process times associated with high costs would be required for filling the blind holes. If pores having a diameter of, for example, more than 50 μm are used for producing the vias, then the filling of the pores with metal may, if appropriate, also be effected by means of an electrochemical deposition method (ECD). The requisite conductive seed layer on the insulator layer may be produced in this case by means of sputtering (PVD=Physical Vapor Deposition) and/or CVD (Chemical Vapor Deposition) methods. Sputtering methods are not suitable for filling pores or blind holes with the dimensions and aspect ratios sought according to the invention. At high aspect ratios (large depth, small diameter), it is not possible to deposit sputtered material into the blind hole in such a way that the hole is homogeneously filled with material. Moreover, the layer thicknesses that can be produced by means of sputtering methods with economically practical process times are typically in the range of a few hundred nanometers. By contrast, the pores sought according to the invention preferably have a depth in the range of 100 to 250 μm and a diameter of preferably 5 to 30 μm.

In the next process step (vii), the uncovered part of the insulator layer 30 which defined the pore end or blind hole end of the uncovered blind holes 21 is removed by means of a wet- or dry-chemical etch, by means of mechanical grinding or by means of ultrasound. FIG. 1F shows the substrate 10 after removal of the blind hole ends 21 uncovered in regions after carrying out step (vii) in accordance with the method of the present invention. From the previously produced blind holes 20, passage holes 22 filled with metal or a metal alloy 40 are produced by this step.

A substrate having good thermal conductivity with contacts which connect the first surface 11 to the second surface 12 with good electrical conductivity, each contact being electrically insulated from every other contact and, moreover, each contact being well insulated electrically from the substrate, is obtained in accordance with the method of the present invention. On account of the insulator thickness, the parasitic capacitance of the substrate itself is low. In particular, the type of process implementation presented here, provided that the thermal oxidation is also employed as a process for the application of the second insulator layer, affords the advantage that all substrate surfaces are reliably insulated and a very high yield can thus be achieved in the production of the substrate according to the invention.

A further major advantage of the process implementation described consists in the fact that the filling of the pores with metal can be effected at very high temperatures of between 400 and 700° C. During the cooling and contraction of the metal in the pores, small cavities arise between the insulator and the metal along the metal-filled pores. Since the finished chip carrier in the product must withstand large temperature fluctuations and the metal in the pores expands again upon heating during operation, the cavities prove to be highly advantageous in that they make available to the metal free volume for expansion. Without this expansion volume, the metal upon heating would expand to a very great extent along the longitudinal axis of the via beyond the first and second surfaces of the substrate and thereby raise and damage the layers situated on the top side and underside of the substrate, which would lead to the destruction of the chip carrier substrate.

The substrate processed according to the invention affords the advantage that it can be processed further by means of conventional processes and apparatuses of the semiconductor industry on account of the materials used and when using standard substrate formats (wafers). In particular, on account of the thermal stability of the substrate and the metal filling, on one or on both surfaces of the substrate, one or a plurality of metal layers may be applied using thin film technology by means of e.g. sputtering or CVD methods or else by electrochemical deposition and be patterned photolithographically.

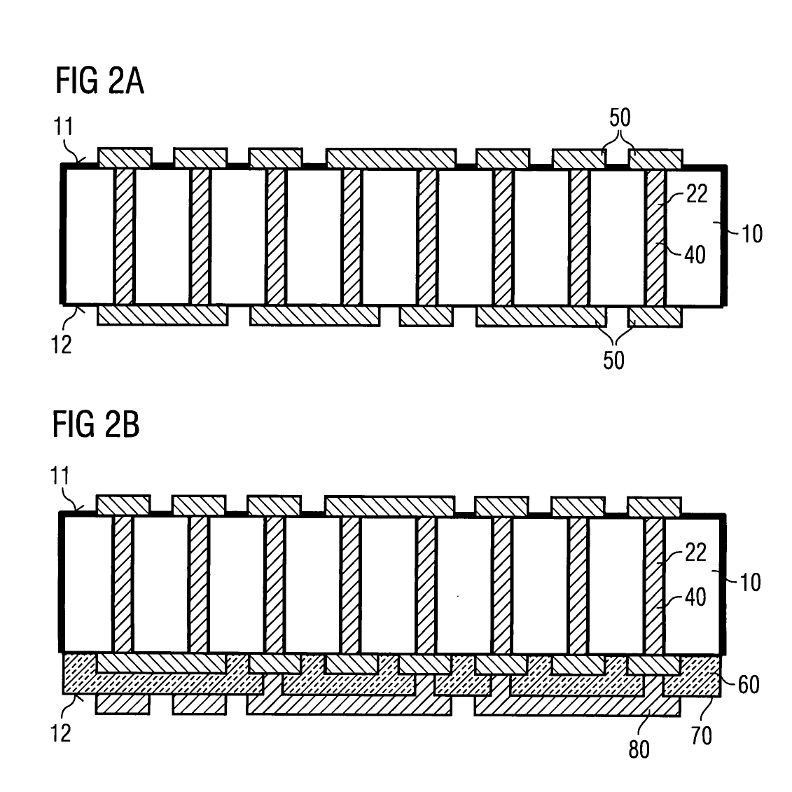

It is thereby possible to produce conductor tracks (redistribution layers) in order to make voltages and currents available on the surface at arbitrary positions (cf. FIGS. 2A and 2B). FIG. 2A shows the substrate according to the invention with conductor tracks 50 arranged photolithographically on both surface sides 11, 12. A predetermined number of the conductor tracks 50 may be conductively connected by means of at least one metal filling 40. It is therefore possible according to the invention for conductor tracks 50 situated on opposite surfaces 11, 12 of the substrate 10 to be conductively connected to one another. Consequently, voltages and currents can be made available not just at one surface 11, 12, rather it is possible for example to conduct a current from the first surface 11 to the second surface 12 and/or from the second surface 12 to the first surface 11. In particular, it is also possible, therefore, for cross-surface conductive connections to be produced and, by way of example, for electronic components arranged on different surfaces 11, 12 of the substrate 10 to be conductively connected to one another.

FIG. 2B shows a preferred embodiment of the substrate 10 according to the invention such as is also illustrated in FIG. 2A, the electrical conductor tracks 50 being covered at least in regions with an insulator 60 at least on one of the first and second surfaces 11, 12. At least one further electrical conductor track 80, preferably made from a material having good electrical conductivity, for example aluminum or copper, is arranged on a free area 70, in particular a free surface 70 of the insulator 60. The electrical conductor track 80 is preferably produced from the same metal with which the passage hole 22 is also filled or of which the conductor track 50 is composed.

The electrical conductor track 80 can be electrically conductively connected to one or a plurality of the conductor tracks 50 which are arranged on the second surface 12 of the substrate, through the insulator 60. The electrical conductor track 80 in turn may be connected for example to further electrical conductor tracks and/or one or a plurality of electrical or electronic components. Consequently, a multiplicity of electrically conductive connections may be provided in a simple manner.

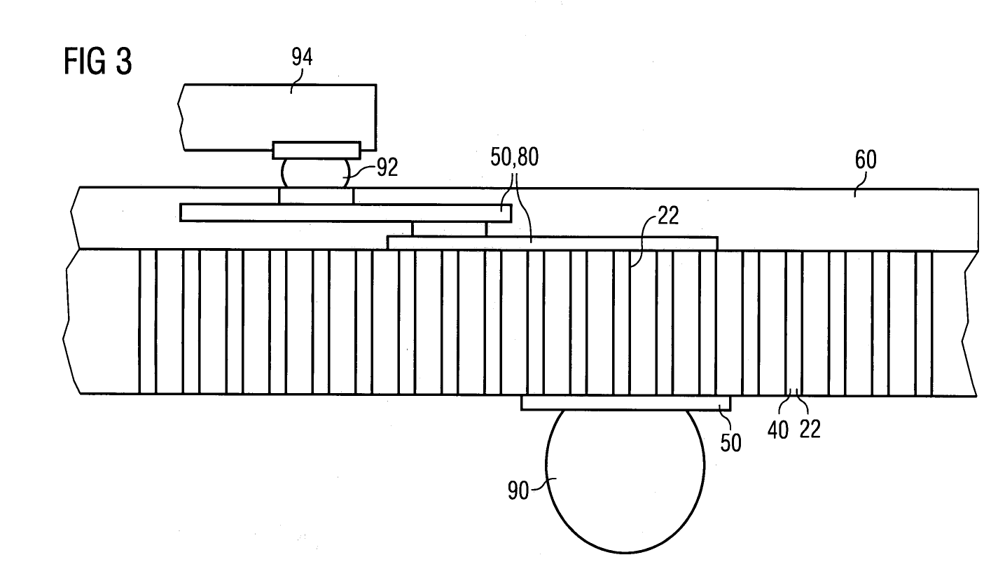

FIG. 3 shows an exemplary application of the chip carrier according to the invention in conjunction with known standard flip-chip interconnects 90 as a preferred electronic component arranged on the first surface 11, by way of example, and a face-to-face interconnect 92, as a further preferred electronic component, arranged on the second surface 12 of the substrate 10. The face-to-face interconnect 92 is electrically conductively connected to the standard flip-chip interconnect 90 by means of the conductor tracks 50, 80 through the substrate 10, the electrical connection through the substrate 10 being produced by means of the passage holes 22 and the metal 40 arranged therein and also the conductor tracks 50, 80 arranged on the surfaces 11, 12 of the substrate 10.

Furthermore, FIG. 3 illustrates a photolitho-graphically patternable polyimide 60 as preferred insulator, which spaces apart or isolates the metallic conductor track 50 from the metallic conductor track 80, electrical contact between the conductor track 50 and the conductor track 80 being possible through the polyimide 60.

Furthermore, FIG. 3 shows a semiconductor-based chip 94 (silicon IC die), which is electrically conductively connected to the face-to-face interconnect 92. The chip 94 is consequently electrically conductively connected to the standard flip-chip interconnect 90, whereby communication between the chip 94 and the standard flip-chip interconnect 90 is made possible in a simple manner.

A further advantage of the parallel connection of small contact holes that can be realized by means of the present invention, as mentioned in the introduction, consists in the fact that it is possible to save costs in the sense that a universal substrate with vias can be produced which does not have to be adapted in a product-specific manner. For this purpose, the vias are distributed completely homogeneously on the wafer, that is to say that the distance between the vias is constant in the x and y directions over the entire wafer and is in each case 10 μm e.g. in both directions. Therefore, vias are produced even in the region in which they are not required. The product-specific design arises only as a result of the photolithographic definition of the conductor tracks on the top side and underside of the substrate. It is thus possible to dispense with the alignment of the contact areas between via and conductor track on the top side and underside of the substrate. The size of the contact areas defines the number of vias connected in parallel. FIG. 3 illustrates these facts.

The chip carrier substrate according to the invention is also particularly advantageous with regard to the connection technology. Since space-saving face-to-face interconnects can be used, the area taken up can be considerably reduced in contrast to chip carrier substrates that are connected to the chip by means of wire bonding.

What is claimed is:

1. A method for producing a metal-filled or alloy-filled substrate based on macroporous silicon, which is suitable as a carrier for microelectronic components, comprising:
(i) producing blind holes having a depth in a range of 25 to 1000 μm and a diameter in a range of 5 to 150 μm from a first front-side surface of the silicon substrate;
(ii) producing an insulator layer on the first front-side surface and a second, rear-side surface of the substrate;
(iii) performing selective isotropic etching from the second, rear-side surface with uncovering of blind hole ends produced in step (ii) such that respective blind hole walls formed by the insulator layer produced in step (ii) project from the substrate on the rear-side surface and are defined in this region only by the insulator layer forming the respective blind hole walls;
(iv) producing a further insulator layer on the surfaces of the substrate obtained in step (iii);
(v) filling a plurality of the blind holes with a metal or a metal alloy by introducing the substrate obtained in step (iii) or (iv) into a melt thereof under pressure in a process chamber containing the melt;
(vi) asymmetrically cooling the melt in the blind holes from the front-side surface, so that the metal or the alloy contracts upon cooling in the blind holes toward the rear-side surface until the solidified metal surface lies on a plane with the rear-side surface of the substrate; and
(vii) removing any remaining unfilled blind hole ends that project from the substrate and are formed only by the insulator layer in this region.

2. The method as claimed in claim 1, wherein the step of producing the blind holes is achieved by electrochemical etching, reactive ion etching, or laser drilling.

3. The method as claimed in claim 1, wherein the step of producing the insulator layer is effected by thermal oxidation of the silicon substrate.

4. The method as claimed in claim 1, wherein in step (iii) the insulator layer is removed from the second, rear-side surface by wet- or dry-chemical etching and the silicon is subsequently wet-chemically etched on one side using KOH or TMAH.

5. The method as claimed in claim 1, wherein step (v) comprises:
dipping the substrate into the melt; and
applying pressure in a range of 1 to 20 bar to the process chamber.

6. The method as claimed in claim 5, wherein the melt is an aluminum melt.

7. The method as claimed in claim 1, wherein step (v) comprises:
dipping the substrate into the melt; and
applying pressure in a range of 5 to 10 bar to the process chamber.

8. The method as claimed in claim 7, wherein the melt is an aluminum melt.

9. The method as claimed in claim 1, wherein in step (v), high-purity dry nitrogen or a high-purity dry noble gas is used as process gas in the process chamber for generating the pressure in the course of filling with liquid metal.

10. The method as claimed in claim 1, wherein in step (vi), after the substrate has been pulled from the melt, the cooling of the first surface is accelerated using a water-cooled metal plate opposite the first surface or the cooling of the melt from the rear side of the substrate is prevented or slowed using a lamp heating system or a heated metal surface so that the solidification of the metal in the pores is in each case effected from the front side toward the rear side.

11. The method as claimed in claim 1, wherein in step (vii), the removal is effected using wet- or dry-chemical etching.

12. A metal-filled or alloy-filled substrate based on macroporous silicon, suitable as a carrier for microelectronic components, the substrate comprising:
a first surface;
a second surface situated opposite to the first surface;
a plurality of discrete passage holes having a diameter in a range of 5 to 150 μm and being distributed over the entire surface region; and
an insulator layer covering the first and second surfaces and inner walls of the passage holes of the substrate,
wherein the passage holes are completely filled with metal or a metal alloy, so that the metal-filled passage holes electrically contact-connect the metallization planes of the first and second surfaces to one another, the contacts in each case being electrically insulated from one another and from the substrate.

13. The substrate as claimed in claim 12, wherein the metal for filling the passage holes is selected from the group consisting of aluminum and an alloy thereof with silicon and/or copper.

14. The substrate as claimed in claim 12, wherein the metal-filled passage holes have an aspect ratio in a range of 1:5 to 1:50.

15. The substrate as claimed in claim 12, wherein the density of the filled passage holes is in a range of 10⁴ to 10⁶/cm².

16. The substrate as claimed in claim 12, wherein the thickness of the substrate is between 25 and 1000 μm.

17. The substrate as claimed in claim 12, wherein the thickness of the substrate is between 100 and 250 μm.

18. The substrate as claimed in claim 12, wherein the insulator layer is based on SiO₂ or Si₃N₄.

19. The substrate as claimed in claim 12, wherein the thickness of the insulator layer is 10 to 2000 nm.

20. The substrate as claimed in claim 12, further comprising conductor tracks arranged on the first and second surfaces, wherein at least two of the conductor tracks are connected by one of the metal-filled passage holes.

21. The substrate as claimed in claim 20, further comprising an insulator covering the conductor tracks on at least one of the first and second surfaces.

22. The substrate as claimed in claim 21, further comprising at least one further conductor track arranged on a free surface of the insulator, wherein the at least one further conductor track is electrically connected one or a plurality of the conductor tracks.

23. The use of the substrate as claimed in claim 10 as a carrier for one or more microelectronic components on one or both substrate surface sides.

24. A method for producing a macroporous silicon substrate suitable as a carrier for microelectronic components, the method comprising:
(i) producing blind holes from a front surface of the substrate;
(ii) producing an insulator layer on the front and rear surfaces of the substrate;
(iii) performing selective etching from the rear surface with uncovering of blind hole ends produced such that respective blind hole walls formed by the insulator layer project from the substrate on the rear surface and are defined in this region only by the insulator layer forming the respective blind hole walls;
(iv) producing a further insulator layer on the surfaces of the substrate;
(v) filling a plurality of the blind holes with a metal or a metal alloy by introducing the substrate into a melt thereof under pressure in a process chamber containing the melt;
(vi) asymmetrically cooling the melt in the blind holes from the front surface, so that the metal or the alloy contracts toward and lies on a plane with the rear surface of the substrate; and
(vii) removing any remaining unfilled blind hole ends that project from the substrate.

25. A metal-filled or alloy-filled macroporous silicon substrate suitable as a carrier for microelectronic components, the substrate comprising:
a first surface;
a second surface situated opposite to the first surface;
a plurality of passage holes distributed over the entire surface region; and
an insulator layer covering the first and second surfaces and inner walls of the passage holes,
wherein a plurality of the passage holes are completely filled with metal or a metal alloy, so that the metal-filled passage holes electrically contact-connect the metallization planes of the first and second surfaces to one another, the contacts in each case being electrically insulated from one another and from the substrate.
